(19) United States
(12) Patent Application Publication
(10) Pub. No.: US 2026/0107462 A1
(43) Pub. Date: Apr. 16, 2026

(54) ERASABLE PROGRAMMABLE NON-VOLATILE MEMORY CELL

(71) Applicant: eMemory Technology Inc., Hsin-Chu (TW)

(72) Inventor: Wein-Town SUN, Hsinchu County (TW)

(21) Appl. No.: 19/357,835

(22) Filed: Oct. 14, 2025

Related U.S. Application Data
(60) Provisional application No. 63/706,767, filed on Oct. 14, 2024.

(51) Int. Cl. H10B 41/70; H10B 41/35

(52) U.S. Cl. CPC H10B 41/70; H10B 41/35

(57) ABSTRACT

A non-volatile memory cell includes an isolation structure, a first well region, a second well region, a first gate structure, a first spacer and a metal layer. The surface of the semiconductor substrate is divided into a first region and a second region by the isolation structure. The first well region is formed in the first region. The second well region is formed in the second region. The first gate structure is formed on the surface of the first region and the surface of the second region. The first spacer is formed on a sidewall of the first gate structure. A first merged doped region and a second merged doped region are formed under the surface of the first region. A third merged doped region is formed under the surface of the second region. The metal layer is formed over the first gate structure.

This application claims the benefit of US provisional application Serial No 63/706,767, filed October 14, 2024, the subject matters of which is incorporated herein by reference

### FIELD OF THE INVENTION

The present invention relates to a non-volatile memory, and more particularly to an erasable programmable non-volatile memory cell.

### BACKGROUND OF THE INVENTION

As is well known, non-volatile memories (MVMs) have been widely used in a variety of electronic devices such as SD cards or solid state drives (SSDs). Generally, an erasable programmable non-volatile memory includes a memory array. The memory array includes a plurality of erasable programmable non-volatile memory cells.

For example, each erasable programmable non-volatile memory cell includes a floating gate transistor. The floating gate of the floating gate transistor can store hot carriers. The storage state of the floating gate transistor can be determined according to the amount of stored hot carriers. For example, the hot carriers are electrons or holes.

Nowadays, by using the CMOS manufacturing process, IO devices capable of withstanding higher voltages and core devices capable of withstanding lower voltages can be formed on a single piece of semiconductor substrate. The core devices are also referred to as low voltage devices (or LV devices) such as LV P-type transistors and LV N-type transistors. The IO devices are also referred as medium voltage devices (or MV devices) such as MV P-type transistors and MV N-type transistors. Since the gate oxide layer of the LV device is thinner, the LV device is only able to withstand the lower voltage stress. However, the operation speed of the LV device is faster. The gate oxide layer of the MV device is thick enough to withstand the higher voltage stress. However, the operation speed of the MV device is slower.

When a program action or an erase action is performed on the erasable programmable non-volatile memory cell, the erasable programmable non-volatile memory cell needs to receive a higher program voltage or a higher erase voltage. For example, the erase voltage is approximately in the range between 14V and 19V, and the program voltage is approximately in the range between 7.5V and 9V. In other words, the transistors in the erasable programmable non-volatile memory cell (e.g., including the floating gate transistor) are MV devices. Consequently, the erasable programmable non-volatile memory cell needs to comply with the design rules of the MV device. For example, the gate channel length of the transistor in the MV device is at least 0.45 μm.

Due to the design rules of the MV device, the size of the conventional erasable programmable non-volatile memory cell is usually too large.

### SUMMARY OF THE INVENTION

An embodiment of the present invention provides an erasable programmable non-volatile memory cell. The erasable programmable non-volatile memory cell includes an isolation structure, a first well region, a second well region, a first gate structure, a first spacer, a first merged doped region, a second merged doped region, a third merged doped region, a metal layer, a bit line, a control line, an assist line, a MOS capacitor and a plate capacitor. The isolation structure is formed on the semiconductor substrate. A surface of the semiconductor substrate is divided into a first region and a second region by the isolation structure. The first well region is formed under a surface of the first region of the semiconductor substrate. The second well region is formed under a surface of the second region of the semiconductor substrate. The first gate structure is formed on the surface of the first region and the surface of the second region. The first spacer is formed on a sidewall of the first gate structure. The first merged doped region and the second merged doped region are formed under the surface of the first region. The first merged doped region is located beside a first side of the first gate structure. The second merged doped region is located beside a second side of the first gate structure. The third merged doped region is formed under the surface of the second region. The metal layer is formed over the first gate structure. A vertical projection area of the metal layer completely covers the first gate structure. The bit line is electrically connected with the second merged doped region. The control line is electrically connected with the third merged doped region. The assist line is connected with the metal layer. A first terminal of the MOS capacitor is electrically connected with the control line. A second terminal of the MOS capacitor is electrically connected with the first gate structure. A first terminal of the plate capacitor is electrically connected with the metal layer. A second terminal of the plate capacitor is electrically connected with the first gate structure. The first merged doped region, the first gate structure and the second merged doped region are collaboratively formed as a floating gate transistor.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIGS. 1A to 1I schematically illustrate the steps of a method of manufacturing an erasable programmable non-volatile memory cell according to a first embodiment of the present invention;

FIG. 1J is a schematic equivalent circuit diagram of the erasable programmable non-volatile memory cell according to the first embodiment of the present invention;

FIGS. 2A to 2F are schematic top views illustrating the steps of a method of manufacturing an erasable programmable non-volatile memory cell according to a second embodiment of the present invention;

FIG. 3A is a bias voltage table illustrating the bias voltages for performing a program action, an erase action and a read action on the memory cell of the first embodiment of the present invention;

FIG. 3B is a schematic circuit diagram the operations of performing the program action on the memory cell of the first embodiment of the present invention;

FIG. 3C is a schematic circuit diagram the operations of performing the erase action on the memory cell of the first embodiment of the present invention;

FIG. 3D is a schematic circuit diagram the operations of performing the read action on the memory cell of the first embodiment of the present invention;

FIG. 4A is a schematic timing waveform diagram illustrating a first example of the bias voltages provided to the control line, the source line and the N-well region of the memory cell when the program action is performed;

FIG. 4B is a schematic timing waveform diagram illustrating a second example of the bias voltages provided to the control line, the source line and the N-well region of the memory cell when the program action is performed;

FIG. 4C is a schematic timing waveform diagram illustrating a third example of the bias voltages provided to the control line, the source line and the N-well region of the memory cell when the program action is performed;

FIG. 4D is a schematic timing waveform diagram illustrating a fourth example of the bias voltages provided to the control line, the source line and the N-well region of the memory cell when the program action is performed;

FIG. 4E is a schematic timing waveform diagram illustrating a fifth example of the bias voltages provided to the control line, the source line and the N-well region of the memory cell when the program action is performed;

FIG. 4F is a schematic timing waveform diagram illustrating a sixth example of the bias voltages provided to the control line, the source line and the N-well region of the memory cell when the program action is performed;

FIG. 5 is a schematic cross-sectional view illustrating the structure of a memory cell according to a third embodiment of the present invention;

FIG. 6 is a schematic cross-sectional view illustrating the structure of a memory cell according to a fourth embodiment of the present invention;

FIG. 7 is a schematic cross-sectional view illustrating the structure of a memory cell according to a fifth embodiment of the present invention;

FIG. 8 is a schematic cross-sectional view illustrating the structure of a memory cell according to a sixth embodiment of the present invention;

FIG. 9A is a schematic cross-sectional view illustrating the structure of a memory cell according to a seventh embodiment of the present invention;

FIG. 9B is a schematic equivalent circuit diagram of the erasable memory cell according to the seventh embodiment of the present invention; and

FIG. 10 is a schematic cross-sectional view illustrating the structure of a memory cell according to an eighth embodiment of the present invention.

### DETAILED DESCRIPTION OF PREFERRED EMBODIMENTS

As mentioned above, in the CMOS manufacturing process, MV devices and LV devices are formed on a single piece of semiconductor substrate. The present invention provides an erasable programmable non-volatile memory cell. By using the manufacturing method including a medium voltage (MV) production procedure and a low voltage (LV) production procedure, the erasable programmable non-volatile memory cell is manufactured. That is, for designing the structure of the erasable programmable non-volatile memory cell of the present invention, a portion of the structure is manufactured according to the design rule of the MV device, and another portion of the structure is manufactured according to the design rule of the LV device. Consequently, the size of the erasable programmable non-volatile memory cell will be reduced, and the program voltage and the erase voltage provided to the memory cell will be decreased. For well understanding the concepts of the present invention, some embodiments of the memory cell will be described as follows.

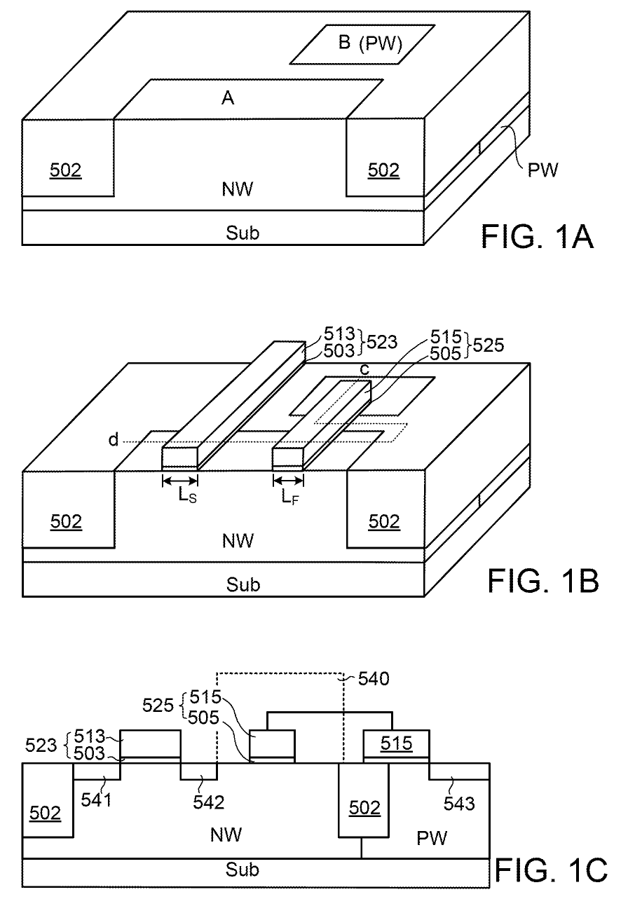

FIGS. 1A to 1I schematically illustrate the steps of a method of manufacturing an erasable programmable non-volatile memory cell according to a first embodiment of the present invention. FIG. 1J is a schematic equivalent circuit diagram of the erasable programmable non-volatile memory cell according to the first embodiment of the present invention. For brevity, the erasable programmable non-volatile memory cell is referred herein as a memory cell.

As shown in FIG. 1A, an isolation structure forming step is performed. An isolation structure 502 is formed on a semiconductor substrate Sub. Due to the isolation structure 502, a region A and a region B are defined. The semiconductor substrate Sub is covered by the isolation structure 502. The surface of the semiconductor substrate Sub corresponding to the region A and the region B is exposed. For example, the isolation structure 502 is a shallow trench isolation (STI) structure. In this embodiment, a memory cell is constructed on the region A and the region B.

Then, a well region forming step is performed. Consequently, a first well region is formed under the surface of the semiconductor substrate Sub corresponding to the region A, and a second well region is formed under the surface of the semiconductor substrate Sub corresponding to the region B. For example, the first well region is an N-well region NW, the second well region is a P-well region PW, and the semiconductor substrate Sub is a P-type semiconductor substrate P_sub.

Then, a gate structure forming step is performed. As shown in FIG. 1B, two gate structures 523 and 525 are formed. The gate structure 523 includes a gate dielectric layer 503 and a polysilicon gate layer 513. The gate structure 525 includes a gate dielectric layer 505 and a polysilicon gate layer 515. The gate dielectric layer 503 is contacted with the surface of the N-well region and the surface of the isolation structure 502. The gate dielectric layer 505 is contacted with the surface of the N-well region, the surface of the isolation structure 502 and the surface of the P-well region PW. The polysilicon gate layer 513 is formed on the gate dielectric layer 503. The polysilicon gate layer 515 is formed on the gate dielectric layer 505.

The gate structure 525 is formed on the surface of the region A. In addition, the gate structure 525 is externally extended to the region over the surface of the region B through the surface of the isolation structure 502. The gate structure 523 is formed on the surface of the region A and externally extended to another memory cell (not shown) through the surface of the isolation structure 502. That is, the gate structure 523 is shared by a plurality of memory cells.

The surface of the region A is divided into three sub-regions by the two gate structures 523 and 525. The polysilicon gate layer 515 of the gate structure 525 is served as the floating gate of a floating gate transistor. The polysilicon gate layer 513 of the gate structure 523 is served as a select gate of a select transistor.

In this embodiment, the channel length L_{F} of the floating gate transistor is smaller than the channel length L_{S} of the select transistor, i.e., L_{F}<L_{S}. For example, the channel length L_{S} of the select transistor is 0.55μm, and the channel length L_{F} of the floating gate transistor is 0.35μm.

The subsequent steps of the manufacturing process of the memory cell will be illustrated. In FIGS. 1C, 1D, 1E and 1F, the cross-sectional views of the memory cell in subsequent steps and taken along the dotted line cd in FIG. 1B are shown.

Please refer to FIG. 1C. Then, the gate structure 525 and its two side areas in the region A are covered with a mask 540 shown in dotted lines, and the gate structure 523 and its two side areas are exposed. The region B is not covered with the mask 540, and the gate structure 525 corresponding to the region B and its surrounding areas are exposed (not shown). For example, the mask 540 is formed of a photoresist layer. As shown in FIG. 1B, the memory cell has a single polysilicon gate layer 515. In FIG. 1C, two polysilicon gate layers 515 are connected with each other by a solid line and represented as the same polysilicon gate layer.

Then, a lightly doped drain process (LDD process) in the MV production procedure is performed. Consequently, p-type lightly doped drain regions (p-LDD regions) 541 and 542 are formed under the surface of the semiconductor substrate Sub uncovered by the mask 540 and the gate structure 523. Furthermore, a p-LDD region 543 is formed under the surface of the semiconductor substrate Sub uncovered by the gate structure 525. The p-LDD regions 541 and 542 are formed under the surface of the region A and respectively located beside the two sides of the gate structure 523. The p-LDD region 543 is formed under the surface of the region B and arranged around the gate structure 525. The doping concentrations of the p-LDD regions 541, 542 and 543 are equal, and the doping depths of the p-LDD regions 541, 542 and 543 are equal.

Please refer to FIG. 1D. After the mask 540 is removed, the gate structure 523 and its side areas in the region A are covered with a mask 550 shown in dotted lines. The gate structure 525 in the region B is also covered with the mask 550. In other words, the region previously covered by mask 540 is exposed. For example, the mask 550 is formed of a photoresist layer. Then, an LDD process in the LV production procedure is performed. Consequently, p-type lightly doped drain regions (p-LDD regions) 551 and 552 are formed under the surface of the semiconductor substrate Sub uncovered by the mask 550 and the gate structure 525. The p-LDD regions 551 and 552 are formed under the surface of the region A and respectively located beside the two sides of the gate structure 525. The doping concentrations of the p-LDD regions 551 and 552 are equal, and the doping depths of the p-LDD regions 551 and 552 are equal.

The region between the p-LDD region 541 and the p-LDD region 542 is served as a channel region of the select transistor, and the length of the channel region is L_{S}. The region between the p-LDD region 551 and the p-LDD region 552 is served as a channel region of the floating gate transistor, and the distance of the channel region is L_{F}. In addition, L_{F}<L_{S}.

The first LDD process belongs to the MV production procedure. The second LDD process belongs to the LV production procedure. In other words, the doping concentrations of the p-LDD regions 541, 542 and 543 are less than the doping concentrations of the p-LDD regions 551 and 552, and the doping depths of the p-LDD regions 551 and 552 are shallower than the doping depths of the p-LDD regions 541, 542 and 543.

Please refer to FIG. 1E. After the mask 550 is removed, a spacer 548 is formed on the sidewall of the gate structure 523, and a spacer 558 is formed on the sidewall of the gate structure 525. The spacer 548 is contacted with the sidewall of the gate structure 523. The spacer 558 is contacted with the sidewall of the gate structure 525.

Please refer to FIG. 1F. Then, a p-type ion implantation process is performed on the surface of the semiconductor substrate Sub by using the two gate structures 523 and 555 and the two spacers 548 and 558 as masks. Consequently, three p-type ion implantation regions 561, 562 and 563 shown in oblique lines are formed on three sub-regions of the region A uncovered by the two gate structures 523 and 525 and the two spacers 548 and 558, and a p-type ion implantation region 564 shown in oblique lines are formed on the region B uncovered by the gate structure 525 and the spacer 558. Especially, the p-type ion implantation regions 561, 562, 563 and 564 have the highest doping concentration, and their dopant concentration is greater than the dopant concentration of the p-LDD regions 541, 542, 543, 551 and 552.

Please refer to FIG. 1F again. Then, in the region A, the p-LDD region 541 and the p-type ion implantation region 561 are collaboratively formed as a merged p-doped region 571. The merged p-doped region 571 is formed under the surface of the semiconductor substrate Sub and located beside the first side of the gate structure 523. Similarly, the p-LDD region 542, the p-LDD region 551 and the p-type ion implantation region 562 are collaboratively formed as a merged p-doped region 572. The merged p-doped region 572 is formed under the surface of the semiconductor substrate Sub and arranged between the second side of the gate structure 523 and the first side of the gate structure 525. Similarly, the p-LDD region 552 and the p-type ion implantation region 563 are collaboratively formed as a merged p-doped region 573. The merged p-doped region 573 is formed under the surface of the semiconductor substrate Sub and located beside the second side of the gate structure 525. In the region B, the p-LDD region 543 and the p-type ion implantation region 564 are collaboratively formed as a merged p-doped region 574. The merged p-doped region 574 is formed under the surface of the semiconductor substrate Sub and located beside the gate structure 525. In the region A, the p-LDD region 541 is located under the spacer 548 beside the first side of the gate structure 523, the p-LDD region 542 is located under the spacer 548 beside the second side of the gate structure 523, the p-LDD region 551 is located under the spacer 558 beside the first side of the gate structure 525, and the p-LDD region 552 is located under the spacer 558 beside the second side of the gate structure 525.

The perspective view of the structure of FIG. 1F is shown in FIG. 1G. In the region A, the gate structure 523 and the merged p-doped regions 571 and 572 on its two sides are collaboratively formed as a select transistor M_{S1}. In addition, the gate structure 525 and the two merged p-doped regions 572 and 573 on its two sides are collaboratively formed as a floating gate transistor M _{F1}. In the region B, the gate structure 525, the P-well region PW and the merged p-doped region 574 are collaboratively formed as a MOS capacitor C_{C1}. The MOS capacitor C_{C1}is a PMOS capacitor. In this embodiment, the floating gate transistor M_{F1}and the select transistor M_{S1}are p-type transistors and constructed in the N-well region NW. That is, the body terminal of the floating gate transistor M_{F1}and the body terminal of the select transistor M_{S1}are connected to the N-well region NW.

Please refer to FIG. 1H and FIG. 1I. FIG. 1I is a schematic cross-sectional view of the structure shown in FIG. 1H. Then, a metal layer 580 is formed over the polysilicon gate layer 515 of the gate structure 525. The size of the metal layer 580 is greater than the size of the polysilicon gate layer 515. Consequently, the vertical projection area of the metal layer 580 completely covers the polysilicon gate layer 515 of the gate structure 525. The polysilicon gate layer 515 and the metal layer 580 are collaboratively formed as a metal/poly plate capacitor C_{C2}. After a step of forming metal conductor lines is completed, the memory cell C_{ELL}of the first embodiment is fabricated.

Please refer to FIG. 1H and FIG. 1I again. The merged p-doped region 571 is connected to a source line SL. The merged p-doped region 573 is connected to a bit line BL. The polysilicon gate layer 513 is connected to a word line WL. The metal layer 580 is connected to an assist line AG. The merged p-doped region 574 is connected to a control line CG.

As shown in FIG. 1J, the memory cell C_{ELL} includes a select transistor M_{S}₁, a floating gate transistor M_{F1}, a MOS capacitor C_{C1} and a metal/poly plate capacitor C_{C2}. The gate terminal of the select transistor M_{S1} is connected to the word line WL. The first drain/source terminal of the select transistor M_{S1} is connected to the source line SL. The first drain/source terminal of the floating gate transistor M_{F1} is connected to the second drain/source terminal of the select transistor M_{S1}. The second drain/source terminal of the floating gate transistor M_{F1} is connected to the bit line BL. The first terminal of the MOS capacitor C_{C1} is connected to the floating gate 515 of the floating gate transistor M_{F1}. The second terminal of the MOS capacitor C_{C1} is connected to the control line CG. The first terminal of the metal/poly plate capacitor C_{C2} is connected to the floating gate 515 of the floating gate transistor M_{F1}. The second terminal of the metal/poly plate capacitor C_{C2} is connected to the assist line AG. As mentioned above, the memory cell C_{ELL} of the first embodiment includes two transistors M_{F1} and M_{S1} and two capacitors C_{C1}and C_{C2}. Consequently, the memory cell C_{ELL} may be referred to as a 2T2C memory cell. The MOS capacitor C_{C1} and the metal/poly plate capacitor C_{C2} are used as coupling capacitors. When the erase action is performed, no hot carriers can be transferred through the two coupling capacitors C_{C1}and C_{C2}.

In the region A, the shallower LDD regions are formed as the merged p-doped regions 572 and 573 by using the LV production procedure. Consequently, the floating gate transistor M_{F1}with the shorter channel length L_{F} (e.g., 0.35μm) can be designed. Consequently, the layout area of the memory cell C_{ELL}is reduced.

In accordance with the present invention, the shape of the A region and the shapes of the polysilicon gate layers 513 and 515 can be further modified to control the aspect ratios of the select transistor M_{S1}and the floating gate transistor M_{F1}. In addition, the properties of the select transistor M_{S1}, floating gate transistor M_{F1}and the MOS capacitor C_{C1}will be adjusted accordingly.

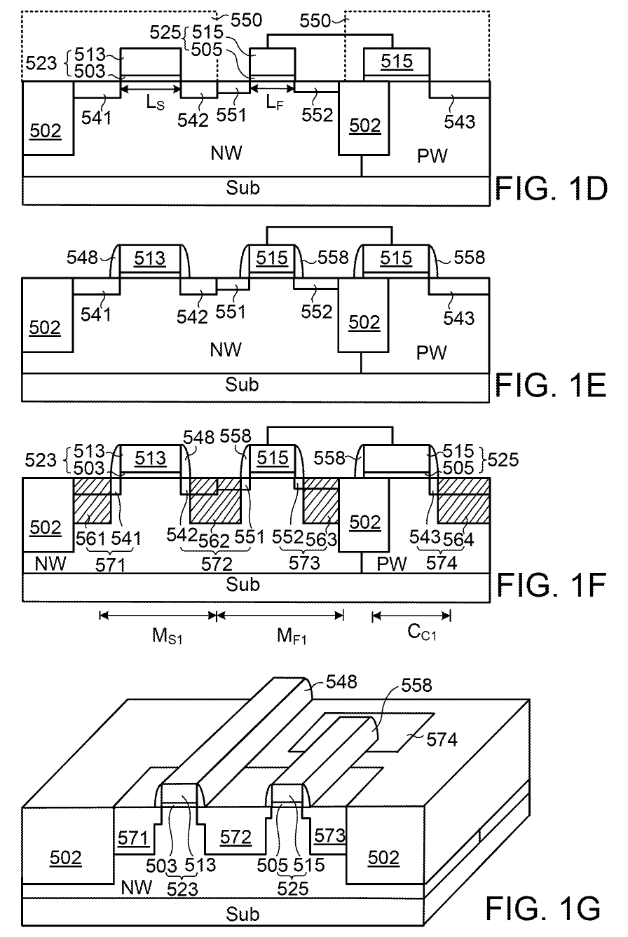

FIGS. 2A to 2F are schematic top views illustrating the steps of a method of manufacturing an erasable programmable non-volatile memory cell according to a second embodiment of the present invention.

As shown in FIG. 2A, an isolation structure 602 is formed on a semiconductor substrate Sub. Due to the isolation structure 602, a region A and a region B are defined. The region B has a square shape. The region A has an inverted-L shape. The width of the region A at the upper side is W_{S}, and the width of the region A at the lower side is W_{F}, wherein W_{S}>W_{F}. After the memory cell is fabricated, the channel width W_{F} of the floating gate transistor is smaller than the channel width W_{S} of the select transistor.

Then, a well region forming step is performed. As shown in FIG. 2B, a first well region is formed under the surface of the semiconductor substrate Sub corresponding to the region A and below the isolation structure 602 near the region A, and a second well region is formed under the surface of the semiconductor substrate Sub corresponding to the region B and below the isolation structure 602 near the region B. For example, the first well region is an N-well region NW, the second well region is a P-well region PW, and the semiconductor substrate Sub is a P-type semiconductor substrate P_sub.

Then, a gate structure forming step is performed. As shown in FIG. 2C, two gate structures are formed. The first gate structure includes a polysilicon gate layer 613. The second gate structure includes a polysilicon gate layer 615. Similarly, the first gate structure is formed on the surface of the region A, and the first gate structure is extended to another memory cell (not shown). The second gate structure is formed on the surface of the region A, and the second gate structure is extended to the region over the surface of the region B.

In the region A, the length L_{F} of the second gate structure is smaller than the length L_{S} of the first gate structure, i.e., L_{F}<L_{S}. That is, after the memory cell is fabricated, the channel length L_{F} of the floating gate transistor is smaller than the channel length L_{S} of the select transistor, i.e., L_{F}<L_{S}. The aspect ratio of the select transistor is (W_{S}/L_{S}). The aspect ratio of the floating gate transistor is (W_{F}/L_{F}). For example, the channel length L_{S} of the select transistor is 0.55μm, and the channel length L_{F} of the floating gate transistor is 0.35μm.

In the B region, the width of the second gate structure is W_{C} and the length of the second gate structure is L_{C}, wherein L_{C}>L_{F}. The oblique overlapping area A_{F} between the second gate structure and the region A is W_{F}×L_{F}. The oblique overlapping area A_{C} between the second gate structure and the region B is W_{C}×L_{C}. In order to increase the coupling ratio of the MOS capacitor, the overlapping area A_{C} is at least three times greater than the overlapping area A_{F}. For example, the overlapping area A_{C} is five times greater than the overlapping area A_{F}.

Then, the steps similar to those of the first embodiment are performed, and thus the structure of FIG. 1G is completed. That is, the LDD process in the MV production procedure, the LDD process in the LV production procedure, the spacer forming process and the ion implantation process are successively performed. As shown in FIG. 2D, three merged p-doped regions 671, 672 and 673 are formed in the first region A, and a merged p-doped region 674 is formed in the region B. The merged p-doped regions 671 and 672 beside the two sides of the polysilicon gate layer 613 contain the p-LDD regions that are formed by the MV production procedure. The merged p-doped regions 672 and 673 beside the two sides of the polysilicon gate layer 615 contain the p-LDD regions that are formed by the LV production procedure.

Please refer to FIG. 2E. Then, a metal layer 680 is formed over the polysilicon gate layer 615 of the second gate structure. The size of the metal layer 680 is greater than the size of the polysilicon gate layer 615. Consequently, the vertical projection area of the metal layer 680 completely covers the polysilicon gate layer 615. The polysilicon gate layer 615 and the metal layer 680 are collaboratively formed as a metal/poly plate capacitor.

Please refer to FIG. 2F. After a step of forming metal conductor lines is completed, the memory cell of the second embodiment is fabricated. The merged p-doped region 671 is connected to a source line SL. The merged p-doped region 673 is connected to a bit line BL. The polysilicon gate layer 613 is connected to a word line WL. The metal layer 680 is connected to an assist line AG. The merged p-doped region 674 is connected to a control line CG.

Like the first embodiment, the memory cell of this embodiment may be referred to as a 2T2C memory cell. The equivalent circuit of this embodiment is similar to that of the first embodiment, and not redundantly described herein. By providing various bias voltages to the memory cell of the first embodiment or the second embodiment, a program action, an erase action or a read action can be selectively performed.

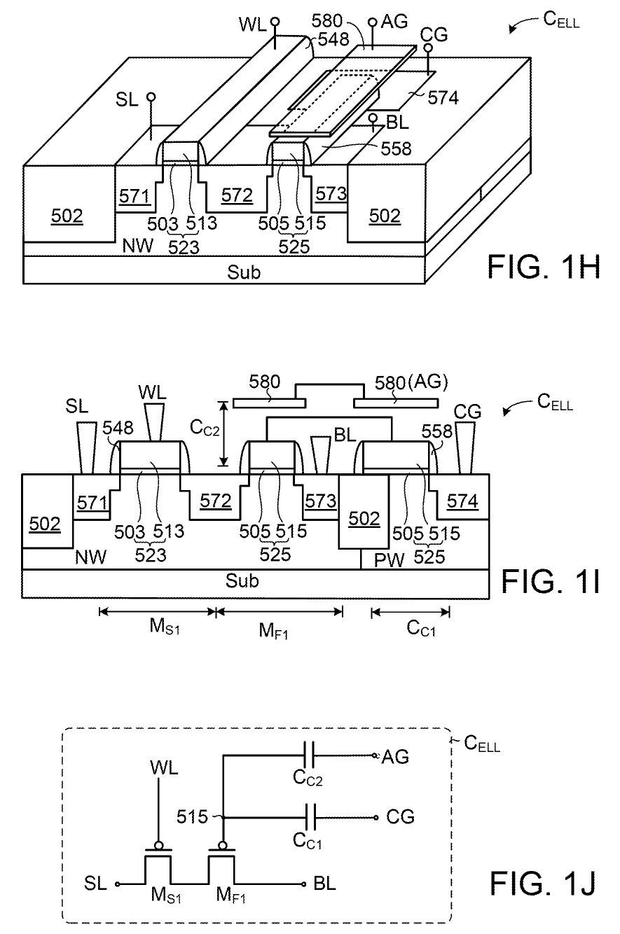

FIG. 3A is a bias voltage table illustrating the bias voltages for performing a program action (PGM), an erase action (ERS) and a read action (Read) on the memory cell of the first embodiment of the present invention. FIG. 3B is a schematic circuit diagram the operations of performing the program action on the memory cell of the first embodiment of the present invention. FIG. 3C is a schematic circuit diagram the operations of performing the erase action on the memory cell of the first embodiment of the present invention. FIG. 3D is a schematic circuit diagram the operations of performing the read action on the memory cell of the first embodiment of the present invention. The N-well region NW and the source line SL receive the same bias voltage. It is noted that the bias voltage table can be applied to the memory cell of the second embodiment.

Please refer to FIG. 3A and FIG. 3B. When the program action is performed, the source line SL receives a program voltage V_{PP}, the word line WL receives a first on voltage V_{ON1}, the bit line BL receives a ground voltage (0V), the control line CG receives a voltage between the ground voltage (0V) and the program voltage V_{PP}, and the assist line AG receives a voltage between a half of program voltage (i.e., 0.5V_{PP}) and twice the program voltage (i.e., 2V_{PP}). For example, the program voltage V_{PP} is in the range between 6V and 6.5V. The first on voltage V_{ON1} is between the ground voltage (0V) and 7/8×VPP.

When the program action is performed, the select transistor M_{S1} is turned on, and a program current I_{P} is generated between the source line SL and the bit line BL. When the hot carriers (e.g., holes) of the program current I_{P} flow through the channel region of the floating gate transistor MF₁, a channel hot hole inducing hot electron injection effect (also referred as a CHHIHE effect) is generated. Since generated electrons are attracted by the voltages from the assist line AG and the control line CL, electrons are injected into the floating gate 615. Meanwhile, the storage state of the memory cell C_{ELL}is changed to a programmed state.

Due to the differences between the merged p-doped regions 571, 572 and 573 in the memory cell C_{ELL}, the program voltage V_{PP} can be reduced, and the programming efficiency can be enhanced.

In the floating gate transistor MF₁of the memory cell of FIG. 1F, the p-LDD regions 551 and 552 near the two sides of the floating gate 515 have higher doping concentrations and shallower depths. Furthermore, the floating gate transistor MF₁has the shorter channel region. Consequently, when the program is performed on the memory cell C_{ELL}, the provision of the lower program voltage V_{PP} can generate a higher electric field at the pinch-off point of the channel region to increase the programming efficiency. Furthermore, in response to the lower program voltage V_{PP}, the program current I_{P} is lower, and the power consumption during the program action is reduced.

Please refer to FIG. 3A and FIG. 3C. When the erase action is performed, the source line SL receives an erase voltage V_{EE}, the word line WL receives a second on voltage V_{ON2}, and the bit line BL receives the erase voltage V_{EE} or is in a floating state. The control line receives the ground voltage (0V). The assist line AG receives a voltage that is lower than or equal to the ground voltage (0V). For example, the erase voltage V_{EE} is in the range between 9V and 12V, and the second on voltage V_{ON2} is lower than or equal to the erase voltage V_{EE}.

When the erase action is performed, the select transistor M_{S1} is turned on. Meanwhile, the erase voltage V_{EE} is transmitted to the floating gate transistor M_{F1} through the source line SL, and the N-well region NW of the floating gate transistor M_{F1} receives the erase voltage V_{EE}. Consequently, a Fowler-Nordheim tunneling effect (also referred as an FN tunneling effect) is generated in the floating gate transistor M_{F1}. Due to the FN tunneling effect, electrons are transferred from the floating gate 515 to the N-well region NW through the gate dielectric layer, and the erase action is completed. That is, when the erase action is performed, electrons are ejected from the floating gate 515 into the body terminal of the floating gate transistor M_{F1}. Meanwhile, the storage state of the memory cell C_{ELL}is changed to an erased state.

Therefore, by increasing the coupling ratio of the MOS capacitor so that the overlapping area A_{C} is at least three times greater than the overlapping area A_{F}_{,} (for example, five times greater), the provision of the lower erase voltage V_{EE} can complete the erase action.

Please refer to FIG. 3A and FIG. 3D. When the read action is performed, the source line SL receives a read voltage V_{R}, the word line WL receives a third on voltage V_{ON}₃, the bit line BL receives the ground voltage (0V), the control line CG receives a voltage between the ground voltage (0V) and the read voltage V_{R}, and the assist line AG receives a voltage between the ground voltage (0V) and the read voltage V_{R}. The third on voltage V_{ON}₃ is lower than or equal to a half of the read voltage (0.5V_{R}). For example, the read voltage V_{R} is 2.5V.

When the read action is performed, the select transistor M_{S1} is turned on, and a read current I_{R} is generated between the source line SL and the bit line BL. The storage state of the memory cell can be determined according to the magnitude of the read current I_{R}. For example, in case that no electrons are stored in the floating gate 515, the magnitude of the read current I_{R} is very low (e.g., nearly zero). Consequently, it is determined that the memory cell C_{ELL}is in the erased state. Whereas, in case that electrons are stored in the floating gate 515, the magnitude of the read current I_{R} is higher. Consequently, it is determined that the memory cell C_{ELL}is in the programmed state.

It is to be noted that, the erase voltage V_{EE} is higher than the program voltage V_{PP}. The program voltage V_{PP} is higher than the read voltage V_{R}. The read voltage V_{R} is higher than the ground voltage (0V).

In an embodiment, fixed bias voltages are provided to the control line CG and the assist line AG when the program action is performed. In some other embodiments, the bias voltages with the gradual increasing waveform are suitably provided to the control line CG and the assist line AG. For example, the gradual increasing waveform is a step waveform, a triangle waveform, or a 1/4 ellipse waveform.

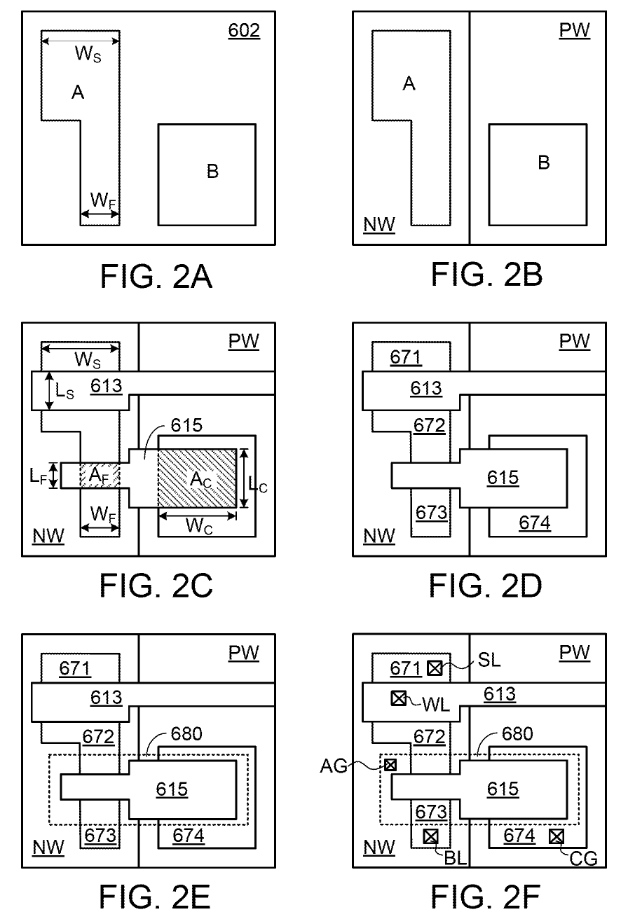

FIG. 4A is a schematic timing waveform diagram illustrating a first example of the bias voltages provided to the control line, the source line and the N-well region of the memory cell when the program action is performed. When the program action is performed, the program cycle is divided into a program phase P1 and a verification phase V1.

The time interval between the time point t₁ and the time point t₆ is the program phase P1. In the program phase P1, the source line SL and the N-well region NW receive the program voltage V_{PP}, and the voltage received by the control line CG is gradually increased from an initial voltage V_{P1} to the program voltage V_{PP}. In the time interval between the time point t₁ and the time point t₂, the voltage received by the control line CG is the initial voltage V_{P1}. In the time interval between the time point t₂ and the time point t₃, the voltage received by the control line CG is equal to the initial voltage V_{P1} plus a voltage increment ΔV (i.e., V_{P1}+ΔV). In the time interval between the time point t₃ and the time point t₄, the voltage received by the control line CG is equal to the initial voltage V_{P1} plus twice the voltage increment ΔV (i.e., V_{P1}+2ΔV). The rest may be deduced by analogy. In the time interval between the time point t₅ and the time point t₆, the voltage received by the control line CG is equal to the program voltage V_{PP}. Similarly, in the program phase P1, the voltage received by the assist line AG has the step waveform and is gradually increased to 2V_{PP}. For brevity, associated descriptions are omitted.

The time interval between the time point t₆ and the time point t₇ is the verification phase V1. The verification process in the verification phase V1 is similar to the read action. That is, the verification process is used to judge the storage state of the memory cell C_{ELL}. In the verification phase V₁, the source line SL and the N-well region NW receive the read voltage V_{R}, and the control line CG receives the ground voltage (0V). Consequently, the storage state of the memory cell C_{ELL} is determined according to the magnitude of the read current I_{R} of the memory cell C_{ELL}. If the verification result indicates that the memory cell C_{ELL} is in the programmed state, the program action is completed. If the verification result indicates that the memory cell C_{ELL} is not in the programmed state, it means that the program action fails. Under this circumstance, the program action may be performed on the memory cell once again, or the memory cell may be determined as a failed cell.

FIG. 4B is a schematic timing waveform diagram illustrating a second example of the bias voltages provided to the control line, the source line and the N-well region of the memory cell when the program action is performed. When the program action is performed, the program cycle is divided into a plurality of program phases P1~Pn and a plurality of verification phases V1~Vn.

The time interval between the time point t₁ and the time point t₂ is the program phase P1. In the program phase P1, the source line SL and the N-well region NW receive the program voltage V_{PP}, and the voltage received by the control line CG is gradually increased from the initial voltage V_{P1} to (V_{P1}+2ΔV). For example, in the time interval between the time point t₁ and the time point t₂, the control line CG receives three consecutive pulses. The heights of the three consecutive pulses are V_{P1}, (V_{P1}+ΔV) and (V_{P1}+2ΔV), respectively.

The time interval between the time point t₂ and the time point t₃ is the verification phase V1. In the verification phase V1, the source line SL and the N-well region NW receive the read voltage V_{R}, and the control line CG receives the ground voltage (0V). If the verification result indicates that the memory cell C_{ELL} is in the programmed state, the program action is completed. Meanwhile, the successive processes in the program phases P2~Pn and the verification phases V2~Vn will not be performed. If the verification result indicates that the memory cell C_{ELL} is not in the programmed state, the successive processes in the next program phase P2 and the next verification phase V2 will be performed.

The time interval between the time point t₃ and the time point t₄ is the program phase P2. In the program phase P2, the source line SL and the N-well region NW receive the program voltage V_{PP}, and the voltage received by the control line CG is increased to (V_{P1}+3ΔV). That is, the control line CG receives one pulse. The height of the pulse is (V_{P1}+3ΔV). In a variant example, the control line CG receives a plurality of pulses in the program phase P2, and the heights of these pulses are gradually increased.

The time interval between the time point t₄ and the time point t₅ is the verification phase V2. In the verification phase V2, the source line SL and the N-well region NW receive the read voltage V_{R}, and the control line CG receives the ground voltage (0V). If the verification result indicates that the memory cell C_{ELL} is in the programmed state, the program action is completed. Meanwhile, the successive processes in the program phases P3~Pn and the verification phases V3~Vn will not be performed. If the verification result indicates that the memory cell C_{ELL} is not in the programmed state, the successive processes in the next program phase and the next verification phase will be performed.

The time interval between the time point t₅ and the time point t₆ is the program phase P3. The rest may be deduced by analogy. The time interval between the time point t₇ and the time point t₈ is the program phase Pn. In the program phase Pn, the source line SL and the N-well region NW receive the program voltage V_{PP}, and the voltage received by the control line CG is increased to the program voltage V_{PP}. That is, the control line CG receives one pulse. The height of the pulse is the program voltage V_{PP}.

The time interval between the time point t₈ and the time point t₉ is the verification phase Vn. In the verification phase Vn, the source line SL and the N-well region NW receive the read voltage V_{R}, and the control line CG receives the ground voltage (0V). If the verification result indicates that the memory cell C_{ELL} is in the programmed state, the program action is completed. If the verification result indicates that the memory cell C_{ELL} is not in the programmed state, it means that the program action fails. Under this circumstance, the program action may be performed on the memory cell once again, or the memory cell may be determined as a failed cell.

Similarly, in the program phases P1~Pn and the verification phases V1~Vn, the voltage received by the assist line AG has the step waveform and is gradually increased to 2V_{PP}. For brevity, associated descriptions are omitted.

FIG. 4C is a schematic timing waveform diagram illustrating a third example of the bias voltages provided to the control line, the source line and the N-well region of the memory cell when the program action is performed. FIG. 4D is a schematic timing waveform diagram illustrating a fourth example of the bias voltages provided to the control line, the source line and the N-well region of the memory cell when the program action is performed.

As shown in FIG. 4C, the voltage received by the control line CG has the triangular waveform. The operations of FIG. 4C are similar to those of FIG. 4A. As shown in FIG. 4D, the voltage received by the control line CG also has the triangular waveform, and the program cycle is divided into a plurality of program phases P1~Pn and a plurality of verification phases V1~Vn.

FIG. 4E is a schematic timing waveform diagram illustrating a fifth example of the bias voltages provided to the control line, the source line and the N-well region of the memory cell when the program action is performed. FIG. 4F is a schematic timing waveform diagram illustrating a sixth example of the bias voltages provided to the control line, the source line and the N-well region of the memory cell when the program action is performed.

As shown in FIG. 4E, the voltage received by the control line CG has the 1/4 ellipse waveform. The operations of FIG. 4E are similar to those of FIG. 4A. As shown in FIG. 4F, the voltage received by the control line CG also has the 1/4 ellipse waveform, and the program cycle is divided into a plurality of program phases P1~Pn and a plurality of verification phases V1~Vn.

Furthermore, the memory cell of the first embodiment or the memory cell of the second embodiment may be modified. In some embodiments, the structure of the coupling capacitor C_{C2} is modified, and thus the voltage coupling ratio is increased.

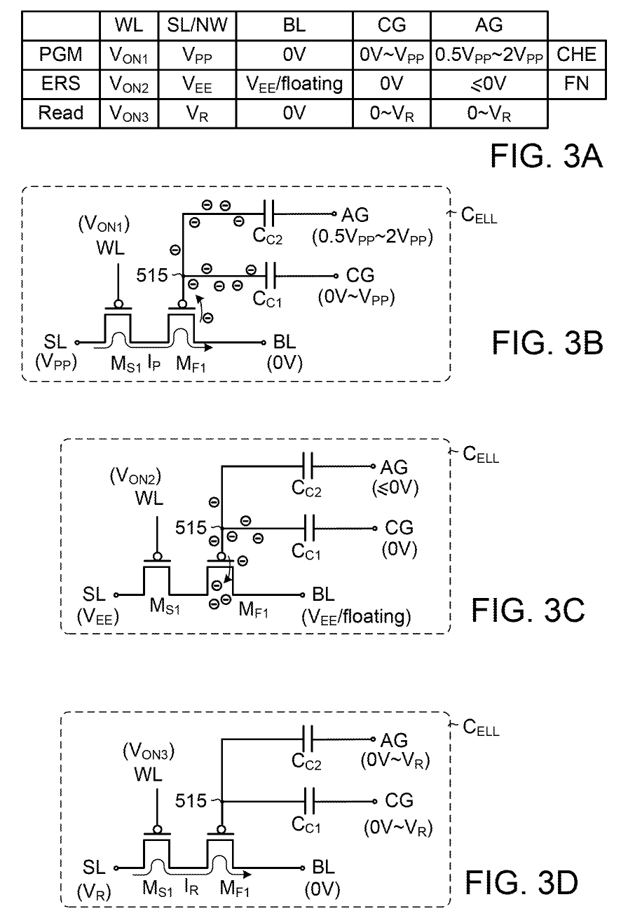

FIG. 5 is a schematic cross-sectional view illustrating the structure of a memory cell according to a third embodiment of the present invention. In comparison with the memory cell C_{ELL} of the first embodiment, the memory cell C_{ELLA}of this embodiment further includes a block layer 702, a polysilicon layer 704 and a conducting line 706. For brevity, only the difference between the two memory cells C_{ELL} and C_{ELLA}will be described as follows.

Please refer to FIG. 5. In the memory cell C_{ELLA}, the gate structure 525 and the spacer 558 are covered by the block layer 702. For example, the block layer 702 is a salicide block layer (SAB) and served as an insulator. The polysilicon layer 704 is formed on the top surface of the block layer 702. That is, the memory cell C_{ELLA}further includes a polysilicon layer 704. The polysilicon layer 704 is arranged between the metal layer 580 and the polysilicon gate layer 515. In addition, the conducting line 706 is arranged between the metal layer 580 and the polysilicon layer 704, and the conducting line 706 is electrically connected with the metal layer 580 and the polysilicon layer 704. Consequently, the polysilicon layer 704 and the polysilicon gate layer (i.e., the floating gate) 515 are collaboratively formed as the polysilicon/polysilicon plate capacitor C_{C2}. Since the distance between the two polysilicon layers 704 and 515 is shorter, the voltage coupling ratio of the coupling capacitor can be effectively enhanced.

The equivalent circuit of the memory cell C_{ELLA}of this embodiment is similar to that of the memory cell C_{ELL} of the first embodiment, and not redundantly described herein. By providing various bias voltages to the memory cell C_{ELLA}of this embodiment according to the bias voltage table of FIG. 3A, a program action, an erase action or a read action can be selectively performed.

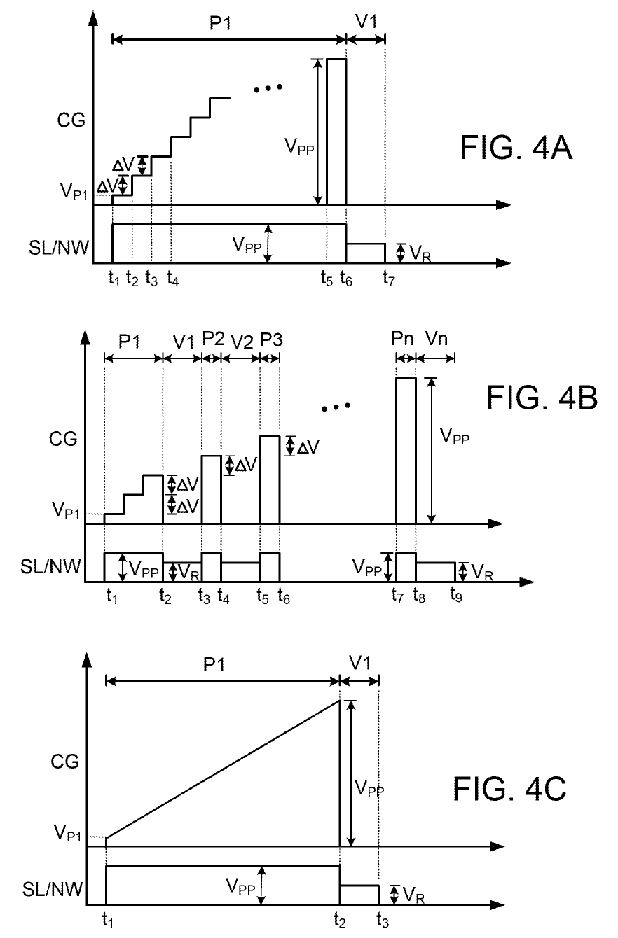

The merged p-doped regions 571, 572 and 573 of the memory cell of the first embodiment can be further modified. FIG. 6 is a schematic cross-sectional view illustrating the structure of a memory cell according to a fourth embodiment of the present invention. In comparison with the memory cell C_{ELL} of the first embodiment, the gate structure 723 and the merged p-doped regions 771 and 772 in the memory cell C_{ELLB}of this embodiment are distinguished. The gate structure 723 includes a gate dielectric layer 703 and a polysilicon gate layer 713, and a spacer 748 is formed on the sidewall of the gate structure 723. For brevity, only the difference between the two memory cells C_{ELL} and C_{ELL}_{B} will be described as follows.

In this embodiment, the p-LDD regions in the region A are formed by the LDD process in the LV production procedure, and the p-LDD regions in the region B are formed by the LDD process in the MV production procedure. Consequently, the doping concentrations and the doping depths of the p-LDD regions in the merged p-doped regions 771, 772 and 573 of the memory cell C_{ELLB} are equal. Furthermore, the doping depths of the p-LDD regions in the merged p-doped regions 771, 772 and 573 are shallower than the doping depth of the p-LDD region in the merged p-doped region 574, and the doping concentrations of the p-LDD regions in the merged p-doped regions 771, 772 and 573 are higher than the doping depth of the p-LDD region in the merged p-doped region 574.

As mentioned above, the p-LDD regions in the merged p-doped regions 771 and 772 are formed by using the LDD process in the LV production procedure. Since the length of the gate structure 723 is shortened, the select transistor M_{S1}also has the short channel. Consequently, the layout area of the memory cell C_{ELL}_{B} is reduced.

The equivalent circuit of the memory cell C_{ELL}_{B} of this embodiment is similar to that of the memory cell C_{ELL} of the first embodiment, and not redundantly described herein. By providing various bias voltages to the memory cell C_{ELL}_{B} of this embodiment according to the bias voltage table of FIG. 3A, a program action, an erase action or a read action can be selectively performed.

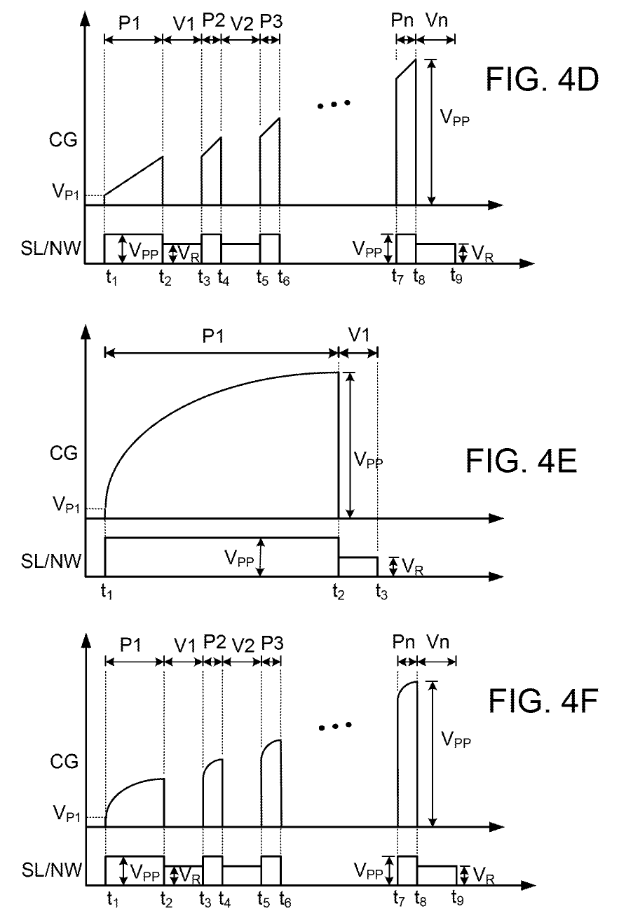

FIG. 7 is a schematic cross-sectional view illustrating the structure of a memory cell according to a fifth embodiment of the present invention. In comparison with the memory cell C_{ELL} of the first embodiment, the MOS capacitor C_{C1} in the memory cell C_{ELLC}of this embodiment is an n-type MOS transistor. For brevity, only the difference between the two memory cells C_{ELL} and C_{ELL}_{C} will be described as follows.

In this embodiment, the second well region in the region B is the N-well region NW. That is, the first well region in the region A and the second well region in the region B are N-well regions NW. As shown in FIG. 7, the two N-well regions NW under the isolation structure 502 are not in contact with each other.

In this embodiment, the LDD process in the MV production procedure is used to form an n-LDD region in the region B, and an n-type ion implantation process is used to form an n-type ion implantation region in the region B. The n-LDD region and the n-type ion implantation region are collaboratively formed as a merged n-doped region 774. Consequently, the gate structure 525, the N-well region NW and the merged n-doped region 774 are collaboratively formed as an n-type MOS capacitor C_{C1}.

The equivalent circuit of the memory cell C_{ELL}_{C} of this embodiment is similar to that of the memory cell C_{ELL} of the first embodiment, and not redundantly described herein. As mentioned above, the MOS capacitor C_{C1}in the memory cell C_{ELL}_{C} is the n-type MOS capacitor. When the program action is performed, the voltage received by the control line CG may be adjusted to be in the range between the ground voltage (0V) and 1.4 times the program voltage V_{PP} (i.e., 1.4V_{PP}). When the erase action or the read action is performed, the bias voltages provided to the memory cell C_{ELL}_{C} of this embodiment are similar to those of the memory cell C_{ELL} of the first embodiment.

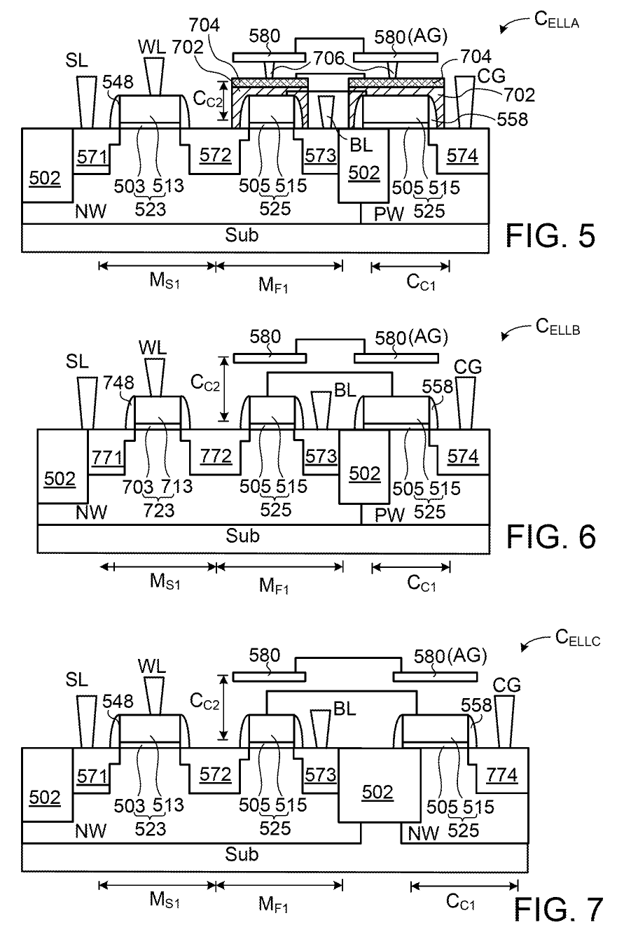

FIG. 8 is a schematic cross-sectional view illustrating the structure of a memory cell according to a sixth embodiment of the present invention. In the memory cell C_{ELL} of the first embodiment, the P-well region PW and the merged p-doped region 574 in the region B have the same dopant type. In contrast, the region B of the memory cell C_{ELL}_{D} of this embodiment includes the P-well region PW and a merged n-doped region 874, which have different dopant types. In addition, the gate structure 525 and the merged n-doped region 874 are collaboratively formed as an n-type MOS capacitor C_{C1}.

The equivalent circuit of the memory cell C_{ELL}_{D} of this embodiment is similar to that of the memory cell C_{ELL} of the first embodiment, and not redundantly described herein. As mentioned above, the P-well region PW and the merged n-doped region 874 have different dopant types. Consequently, when the program action, the erase action or the read action is performed on the memory cell C_{ELL}_{D}, the voltage received by the control line CG needs to be greater than or equal to the voltage received by the P-well region PW. The bias voltages provided to other terminals are similar to those of the first embodiment. For example, when the program action is performed, the voltage received by the control line CG is higher than the program voltage V_{PP}, and the voltage received by the P-well region PW is lower than or equal to the program voltage V_{PP}. When the erase action is performed, the control line CG receives the ground voltage (0V), and the P-well region PW receives the ground voltage (0V). When the read action is performed, the control line CG receives a voltage between the ground voltage (0V) and the read voltage V_{R}, and the P-well region PW receives the ground voltage (0V).

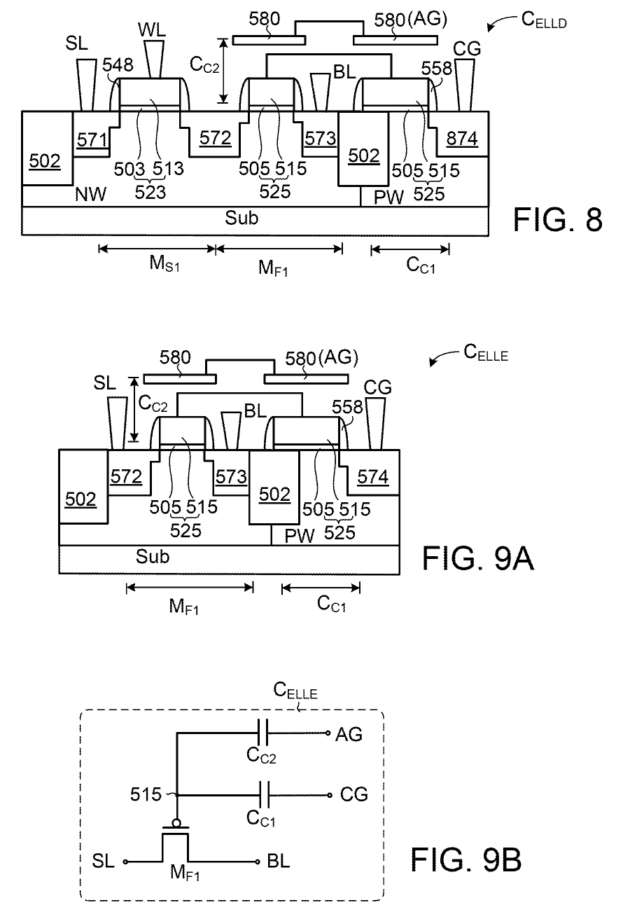

FIG. 9A is a schematic cross-sectional view illustrating the structure of a memory cell according to a seventh embodiment of the present invention. FIG. 9B is a schematic equivalent circuit diagram of the erasable memory cell according to the seventh embodiment of the present invention. In comparison with the memory cell C_{ELL} of the first embodiment, the memory cell C_{ELL}_{E} of this embodiment is not equipped with the select transistor. Consequently, the source line SL is connected to the merged p-doped region 572.

As shown in FIG. 9B, the memory cell C_{ELL}_{E} includes a floating gate transistor M_{F1}, a MOS capacitor C_{C1} and a metal/poly plate capacitor C_{C2}. The first drain/source terminal of the floating gate transistor M_{F1} is connected to the source line SL. The second drain/source terminal of the floating gate transistor M_{F1} is connected to the bit line BL. The first terminal of the MOS capacitor C_{C1} is connected to the floating gate 515 of the floating gate transistor M_{F1}. The second terminal of the MOS capacitor C_{C1} is connected to the control line CG. The first terminal of the metal/poly plate capacitor C_{C2} is connected to the floating gate 515 of the floating gate transistor M_{F1}. The second terminal of the metal/poly plate capacitor C_{C2} is connected to the assist line AG.

As mentioned above, the memory cell C_{ELL}_{E} of this embodiment is not equipped with the select transistor. Consequently, the bias voltage listed in the bias voltage table of FIG. 3A and provided to the word line WL is excluded. By providing other bias voltages to the memory cell, the program action, the erase action or the read action is selectively performed.

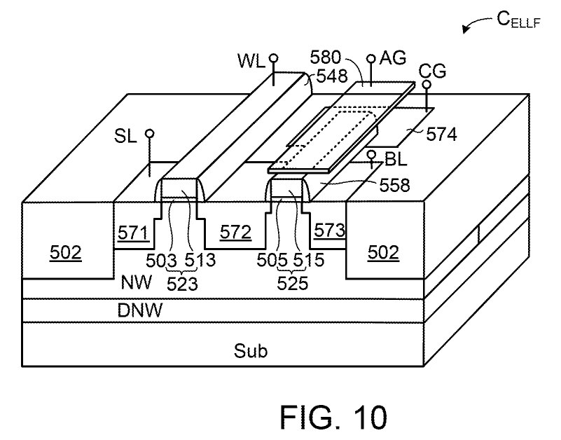

The structure of the memory cell of the first embodiment may be further modified. FIG. 10 is a schematic cross-sectional view illustrating the structure of a memory cell according to an eighth embodiment of the present invention. In the memory cell C_{ELLF}of FIG. 10, a deep N-well (DNW) region is formed between the semiconductor substrate Sub and the N-well region NW. The bottom side of the deep N-well region DNW is contacted with the semiconductor substrate Sub. The top side of the deep N-well region DNW is contacted with the N-well region NW. Similarly, the memory cell in each of the second, third, fourth, fifth, sixth and seventh embodiments is additionally equipped with the deep N-well (DNW) region.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A non-volatile memory cell, comprising:
an isolation structure formed on the semiconductor substrate, wherein a surface of the semiconductor substrate is divided into a first region and a second region by the isolation structure;
a first well region formed under a surface of the first region of the semiconductor substrate;
a second well region formed under a surface of the second region of the semiconductor substrate;
a first gate structure formed on the surface of the first region and the surface of the second region;
a first spacer formed on a sidewall of the first gate structure;
a first merged doped region formed under the surface of the first region, wherein the first merged doped region is located beside a first side of the first gate structure;
a second merged doped region formed under the surface of the first region, wherein the second merged doped region is located beside a second side of the first gate structure;
a third merged doped region formed under the surface of the second region;
a metal layer formed over the first gate structure, wherein a vertical projection area of the metal layer completely covers the first gate structure;
a bit line electrically connected with the second merged doped region;
a control line electrically connected with the third merged doped region;
an assist line connected with the metal layer;
a MOS capacitor, wherein a first terminal of the MOS capacitor is electrically connected with the control line, and a second terminal of the MOS capacitor is electrically connected with the first gate structure; and
a plate capacitor, wherein a first terminal of the plate capacitor is electrically connected with the metal layer, and a second terminal of the plate capacitor is electrically connected with the first gate structure,
wherein the first merged doped region, the first gate structure and the second merged doped region are collaboratively formed as a floating gate transistor.

2. The non-volatile memory cell as claimed in claim 1, further comprising:
a second gate structure formed on the surface of the first region;
a second spacer formed on a sidewall of the second gate structure;
a fourth merged doped region formed under the surface of the first region, wherein the fourth merged doped region is located beside a first side of the second gate structure, and the first merged doped region is arranged between a second side of the second gate structure and the first side of the first gate structure;
a source line electrically connected with the fourth merged doped region; and
a word line electrically connected with the second gate structure,
wherein the fourth merged doped region, the second gate structure and the first merged doped region are collaboratively formed as a select transistor.

3. The non-volatile memory cell as claimed in claim 2, wherein a channel length of the floating gate transistor is smaller than a channel length of the select transistor.

4. The non-volatile memory cell as claimed in claim 2, wherein a channel width of the floating gate transistor is smaller than a channel width of the select transistor.

5. The non-volatile memory cell as claimed in claim 2, wherein there is a first overlapping area between the second gate structure and the first region, and there is a second overlapping area between the second gate structure and the second region, wherein the first overlapping area is at least three times greater than the second overlapping area.

6. The non-volatile memory cell as claimed in claim 2, wherein the first gate structure includes a first gate dielectric layer and a first polysilicon gate layer, and the second gate structure includes a second gate dielectric layer and a second polysilicon gate layer, wherein the first gate dielectric layer is in contact with the surface of the first region and the surface of the second region, the first polysilicon gate layer is in contact with the first gate dielectric layer, the second gate dielectric layer is in contact with a surface of the first region, and the second polysilicon gate layer is in contact with the second gate dielectric layer.

7. The non-volatile memory cell as claimed in claim 6, further comprising:
a block layer covering the first gate structure and the first spacer;
a first polysilicon layer formed on a top surface of the block layer; and
a conducting line electrically connected with the first polysilicon layer and the metal layer,
wherein the first polysilicon gate layer and the first polysilicon layer are collaboratively formed as the plate capacitor, and the plate capacitor is a polysilicon/polysilicon plate capacitor.

8. The non-volatile memory cell as claimed in claim 6, wherein the metal layer and the first polysilicon gate layer are collaboratively formed as the plate capacitor, and the plate capacitor is a metal/poly plate capacitor.

9. The non-volatile memory cell as claimed in claim 6, wherein when a program action is performed, the source line receives a program voltage, the word line receives an on voltage, the bit line receives a ground voltage, the control line receives a voltage between the ground voltage and the program voltage, and the assist line receives a voltage between a half of program voltage and twice the program voltage, wherein when the program action is performed, a channel hot holes inducing hot electron injection effect is generated, and generated electrons are attracted by the voltages from the assist line and the control line and injected into the first polysilicon gate layer of the first gate structure.

10. The non-volatile memory cell as claimed in claim 9, wherein when the program action is performed, the voltage received by the control line has a gradual increasing waveform increased from an initial voltage to the program voltage, wherein the gradual increasing waveform is a step waveform, a triangle waveform or a 1/4 ellipse waveform.

11. The non-volatile memory cell as claimed in claim 6, wherein when an erase action is performed, the word line receives an on voltage, the source line receives an erase voltage, the bit line receives the erase voltage or is in a floating state, the control line receives a ground voltage, and the assist line receives a voltage that is lower than or equal to the ground voltage, wherein when the erase action is performed, a Fowler-Nordheim tunneling effect is generated, and electrons are transferred from the first polysilicon gate layer to the first well region through the first gate dielectric layer.

12. The non-volatile memory cell as claimed in claim 2, wherein the first merged doped region, the second merged doped region, the third merged doped region and the fourth merged doped region are p-type merged doped regions, the first well region is an n-type well region, and the second well region is a p-type well region.

13. The non-volatile memory cell as claimed in claim 2, wherein the first merged doped region, the second merged doped region and the fourth merged doped region are p-type merged doped regions, the third merged doped region is an n-type merged doped region, and the first well region and the second well region are n-type well regions.

14. The non-volatile memory cell as claimed in claim 2, wherein the first merged doped region, the second merged doped region and the fourth merged doped region are p-type merged doped regions, the third merged doped region is an n-type merged doped region, the first well region is an n-type well region, and the second well region is a p-type well region.

15. The non-volatile memory cell as claimed in claim 2, wherein the first merged doped region contains a first ion implantation region, a first lightly doped drain region and a second lightly doped drain region, the second merged doped region contains a second ion implantation region and a third lightly doped drain region, the third merged doped region contains a third ion implantation region and a fourth lightly doped drain region, and the fourth merged doped region contains a fourth ion implantation region and a fifth lightly doped drain region, wherein the second lightly doped drain region is located beside the first side of the first gate structure and under the first spacer, the third lightly doped drain region is located beside the second side of the first gate structure and under the first spacer, the fifth lightly doped drain region is located beside the first side of the second gate structure and under the second spacer, and the first lightly doped drain region is located beside the second side of the second gate structure and under the second spacer.

16. The non-volatile memory cell as claimed in claim 15, wherein a first distance between the fifth lightly doped drain region and the first lightly doped drain region is greater than a second distance between the second lightly doped drain region and the third lightly doped drain region.

17. The non-volatile memory cell as claimed in claim 15, wherein a doping depth of the second lightly doped drain region and a doping depth of the third lightly doped drain region are equal, the doping depth of the third lightly doped drain region is shallower than a doping depth of the fifth lightly doped drain region, the doping depth of the fifth lightly doped drain region and a doping depth of the first lightly doped drain region are equal, and the doping depth of the second lightly doped drain region is shallower than a doping depth of the fourth lightly doped drain region.

18. The non-volatile memory cell as claimed in claim 15, wherein a doping depth of the second lightly doped drain region and a doping depth of the third lightly doped drain region are equal, the doping depth of the third lightly doped drain region and a doping depth of a fifth lightly doped drain region are equal, the doping depth of the fifth lightly doped drain region and a doping depth of the first lightly doped drain region are equal, and the doping depth of the second lightly doped drain region is shallower than a doping depth of the fourth lightly doped drain region.

19. The non-volatile memory cell as claimed in claim 15, wherein a doping concentration of the second lightly doped drain region and a doping concentration of the third lightly doped drain region are equal, the doping concentration of the third lightly doped drain region is greater than a doping concentration of the fifth lightly doped drain region, the doping concentration of the fifth lightly doped drain region and a doping concentration of the first lightly doped drain region are equal, and the doping concentration of the first lightly doped drain region and a doping concentration of the fourth lightly doped drain region are equal.

20. The non-volatile memory cell as claimed in claim 15, wherein a doping concentration of the second lightly doped drain region and a doping concentration of the third lightly doped drain region are equal, the doping concentration of the third lightly doped drain region and a doping concentration of the fifth lightly doped drain region are equal, the doping concentration of the fifth lightly doped drain region and a doping concentration of the first lightly doped drain region are equal, and the doping concentration of the first lightly doped drain region is greater than a doping concentration of the fourth lightly doped drain region.

21. The non-volatile memory cell as claimed in claim 1, further comprising a deep well region, wherein a bottom side of the deep well region is in contact with the semiconductor substrate, and a top side of the deep well region is in contact with the first well region and the second well region.
